(19) United States
(12) Patent Application Publication
(10) Pub. No.: US 2002/0010891 A1
(43) Pub. Date: Jan. 24, 2002

(54) Redundant memory access system

(75) Inventor: Philippe Klein, La Gaude (FR)

Correspondence Address: Blanche E. Schiller, Esq., HESLIN & ROTHENBERG, P.C., 5 Columbia Circle, Albany, NY, 12203, US

(73) Assignee: International Business Machines Corporation, Armonk, NY (US)

(21) Appl. No.: 09/795,419

(22) Filed: Feb. 28, 2001

(30) Foreign Application Priority Data
May 12, 2000 (EP) 00480040.5

(51) Int. Cl. G06F 12/16; G06F 12/00; G06F 12/14; G06F 13/00; G06F 13/28; G11C 29/00

(52) U.S. Cl. 714/767; 711/115; 711/154

(57) ABSTRACT

A system for accessing a memory comprising memorization subsystems (100-1 to 100-10), e.g. standard Dual In-line Memory Modules, wherein the words to be stored are split so that several memorization subsystems are used to store one word and its associated Block Error Code (BEC) bits includes logical insulation means (145-1 to 145-10) that are associated to each memorization subsystem further comprising a backup memorization subsystem (100-11) associated to logical insulation means (145-11). When a memorization subsystem is failing or when a memorization subsystem needs to be changed, the content of this memorization subsystem is corrected thanks to the data stored in the other memorization subsystems and thanks to BEC read path macro (160) and copied in the backup memorization subsystem (100-11)

### PRIOR FOREIGN APPLICATION

This application claims priority from European patent application number 00480040.5, filed May 12, 2000, which is hereby incorporated herein by reference in its entirety.

### TECHNICAL FIELD

The present invention relates to computer memory systems and more particularly to a memory access system and method which improve the availability of memory systems comprising memorization subsystems and allow a memorization subsystem to be automatically replaced without loosing data and perturbing the computer using such memory systems.

### BACKGROUND ART

In today's computers, the memory system is generally made of a plurality of memorization subsystem cards, e.g. Dual In-line Memory Modules (DIMMs). DIMMs are built with several Synchronous Dynamic Random Access Memory (SDRAM) chips, the number of chips depending upon the DIMM memory size, the data bus width, etc. Generally, to store a data in a memorization subsystem card containing several memory chips that can store one byte words, this data is split up into bytes, the first byte is stored in a first memory chip, the second byte in a second memory chip and so on.

These memory chips are subject to different kinds of failures:

soft failures that are intermittent failures due to an external noisy environment, like Alpha particles, that disappear if the data word is rewritten at the failing memory location or after a memory reset.

hard failures that are permanent defects affecting a memory chip, like micro short-circuits, that remain definitively even after memory reset.

These failures, when occurring, may damage the memory system content and then disturb the correct functioning of the current application running on the computer and lead generally to stop this computer in order to replace the failing memorization subsystem card.

To get rid of these failures, Error Correcting Codes (ECC) are generally used to improve the overall memory system failure rate. Indeed, ECC have the capacity to correct automatically errors occurring in a single memory chip without disturbing the functioning of the memory system. To do that, the ECC functions write path function and read path function, that may be located inside the memory controller, are able to detect a failing word and correct it automatically thanks to ECC bits that are stored in additional memory chips on the memorization subsystem card. For example, Single Error Correction (SEC) code can correct one error in a single memory chip, Double Error Correction (DEC) code allows to correct two errors located in the same memory chip, and finally Block Error Code (BEC) allows to correct all errors in a single memory chip. For instance, the 8-bits Block Error Code, derived from the theory of Bose-Chaudhuri-Hocquenghem codes, is able to correct multiple errors randomly distributed in a memory chip. Using two additional bytes per 64 bits length words, this method allows to correct up to 8 bits in a memory chip that can store one byte length words.

However, as the hard failures are remaining defects, the memorization subsystem cards in which hard failures are localized need to be replaced to maintain a high availability of the memory system, i.e. to avoid memory content damages that happen when errors occur in at least two different chips of a same memorization subsystem card. In this case, the user must turn off the computer and replace the failing memorization subsystem cards. Likewise, upgrading the memory system requires to turn off the computer.

### SUMMARY OF THE INVENTION

It is therefore one of the objects of the present invention to provide an improved system for accessing a memory system comprising a plurality of memorization subsystems to increase the availability and the reliability of the computer(s) using such memory system.

It is another object of the present invention to provide an improved system in which a computer memorization subsystem can be changed without disturbing the computer.

It is still another object of the present invention to provide an improved system in which a computer memorization subsystem can be automatically replaced without disturbing the computer.

It is still another object of the present invention to provide a method to copy and to correct the content of a memorization subsystem into another memorization subsystem.

The accomplishment of these and other related objects is achieved by a system for accessing a memory, comprising a plurality of memorization subsystems, independent and removable, said memory being adapted to store words made of n unitary elements, said system comprising:

encoding means to encode each of the n unitary element words to be stored into the memory into a n+m unitary elements word, where the m unitary elements are error correction unitary elements;

word input means for applying each of the n+m elementary elements of a word to a different memorization subsystem of said plurality of memorization subsystems, being able to apply anyone of the n+m elementary elements of a word to at least one of said plurality of memorization subsystems, referred to as backup memorization subsystem;

word output means for accessing each of the n+m elementary elements of a word from said plurality of memorization subsystems;

decoding means responsive to each n+m elementary elements word for producing an error free n unitary elements word; and,

logical insulation means associated to each of said plurality of memorization subsystems, capable of insulate logically each of said plurality of memorization subsystems.

The accomplishment of these and other related objects is also achieved by a method to correct and copy the content of one of a plurality of memorization subsystems, representing unitary elements of words, into a backup memorization subsystem, comprising the steps of:

setting an address index to zero and enabling the set of memorization subsystems storing unitary elements of said words;

disabling said backup memorization subsystem, enabling said one of said plurality of memorization subsystems, reading the word at the location defined by said address index and, if an error is detected, correcting said word using said decoding means;

disabling said one of said plurality of memorization subsystems, enabling said backup memorization subsystem and writing the unitary element contained in said one of said plurality of memorization subsystems, corrected if required, in said backup memorization subsystem at the location defined by said address index;

increasing said address index by one; and,

comparing said address index to the maximum value that can be reached by said address index, if said address index has not reached said maximum value repeating the last 3 steps else if said address index has reached said maximum value ending the process.

Also, a method to correct and copy the content of a backup memory subsystem, representing unitary elements of words, into one of a plurality of memorization subsystems is provided. The method includes:

setting an address index to zero and enabling the set of memorization subsystems storing unitary elements of said words;

disabling said one of said plurality of memorization subsystems, enabling said backup memorization subsystem, reading the word at the location defined by said address index and, if an error is detected, correcting said word using said decoding means;

disabling said backup memorization subsystem, enabling said one of said plurality of memorization subsystems and writing the unitary element contained in said backup memorization subsystem, corrected if required, in said one of said plurality of memorization subsystems at the location defined by said address index;

increasing said address index by one; and,

comparing said address index to the maximum value that can be reached by said address index, if said address index has not reached said maximum value repeating the last 3 steps else if said address index has reached said maximum value ending the process.

The novel features believed to be characteristic of this invention are set forth in the appended claims. The invention itself, however, as well as these and other related objects and advantages thereof, will be best understood by reference to the following detailed description to be read in conjunction with the accompanying drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows the logical part of the circuit that can be used to change a memorization subsystem without perturbing the computer.

FIG. 2 comprising FIG. 2A and FIG. 2B, illustrates read and write path macros that are used to detect, localize and correct failing bits.

FIG. 3 illustrates the power supply circuit associated to the circuit presented in FIG. 1.

FIG. 4 shows the logical part of the circuit implementing the present invention.

FIG. 5 illustrates the power supply circuit optionally associated to the circuit presented in FIG. 4.

FIG. 6 shows the main steps of the algorithm that illustrates the method of the present invention.

FIG. 7 shows a memory system that illustrates the way to extend the amount of memory when using the present invention.

### BEST MODE FOR CARRYING OUT THE INVENTION

According to the invention, the words to be stored are split up into sub-words that are stored in different memorization subsystems, independent and removable. Thus, the first sub-word is stored in a first memorization subsystem, the second sub-word is stored in a second memorization subsystem and so on.

The preferred embodiment of the present invention concerns the use of memorization subsystems, e.g. standard DIMMs, referred to as memory cards for sake of clarity, to store 64 bits words. Nevertheless, it is to be understood that the present invention can be put in use with whatever kind of independent and removable memory to store any length words.

Using the present invention to store 64 bits words, ten memory cards containing memory chips able to store r bytes are required. The first eight memory cards are used to store the data bytes while the last two memory cards are used to store the BEC bytes.

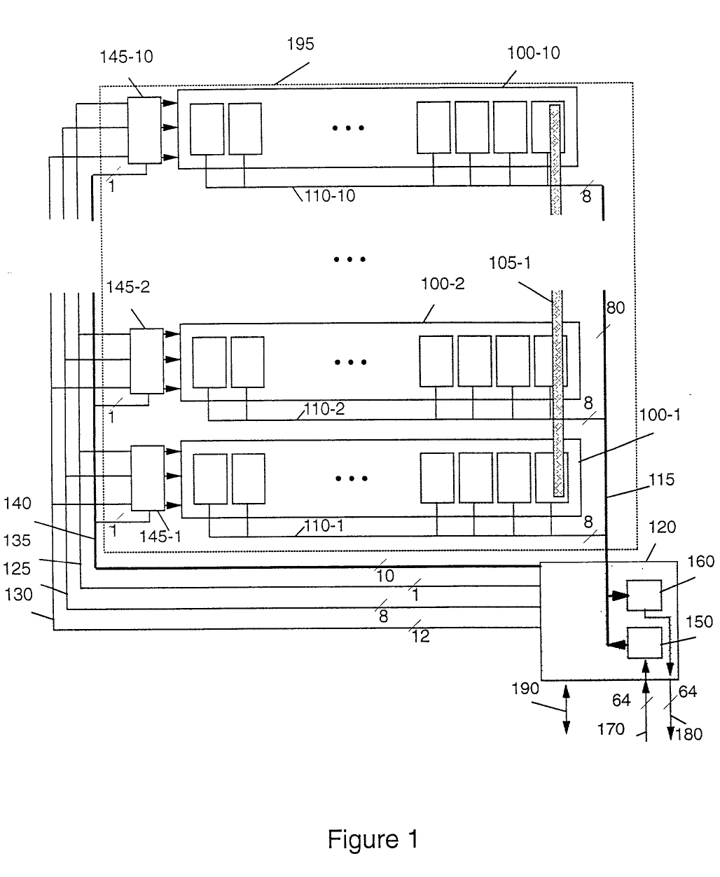

FIG. 1 shows the logical parts of the circuit implementing the present invention that allows to replace a failing memory card without perturbing the computer. As mentioned above, this circuit comprises ten memory cards 100-1 to 100-10. The data input/output buses of the memory chips contained within each memory card are connected together to create the data input/output buses 110-1 to 110-10 that form a global data input/output bus 115 connected to the memory controller 120. The memory controller 120 is also connected to BYTE_Select bus 125, address bus 130, Memory_Card_Select bus 135 and Bus_Insulation bus 140 that are connected to bus-switch components 145-1 to 145-10. Each of these bus-switch components is associated to one memory card to provide or not signals carried by BYTE_Select, address and Memory_Card_Select buses depending upon the signal carried by Bus_Insulation bus. Memory controller 120 contained write path and read path functions (150 and 160 respectively) that are connected to the data input/output bus 115. Write path function is connected to the standard data input bus 170 and read path function is connected to the standard data output bus 180. Memory controller 120 is connected to control bus 190. Buses 170, 180 and 190 are standard buses to connect a memory controller to a computer.

The memory cards 100-1 to 100-8 are used to store the eight data bytes of a 64 bits word and the memory cards 100-9 and 100-10 are used to store its two associated BEC bytes. For instance, the first byte of word 105-1 is stored in the first memory location of the first memory chip of the memory card 100-1, the second byte of this word is stored in the first memory location of the first memory chip of the memory card 100-2 and so on. The 8 bits data input/output of all the memory chips of each memory card are connected together to create busses 110-1 to 110-10 in order to make the 80 bits bus 115 that is connected to the memory controller 120 to exchange data between the memory cards and the computer. To control the addresses and the enabled chips, the memory controller 120 uses BYTE_Select bus 125 and address bus 130. The BYTE_Select bus 125 is used to select memory chips inside a memory card thus, if the memory card comprises 8 memory chips, 8 bits are used to enable or disable each of the 8 memory chips. The address bus 130 selects one memory location in all the memory chips selected with BYTE_Select. In the implementation presented in FIG. 1 this bus comprises 12 bits because generally 12 multiplexed bits are used to define an address, i.e. to select one row and one column in a memory chip. In the present invention, all the ten memory cards 100-1 to 100-10 need to be enabled at the same time to access a complete data thus, Memory_Card_Select bus 135 that is used to activate or inhibit a memory card requires only 1 bit. In order to add or remove a memory card without perturbing the nine other, each of them needs to be electrically and logically insulated independently. Concerning the logical part of this circuit, the BUS_Insulation bus 140, connected to the memory controller 120, commands each of the standard bus-switch components 145-1 to 145-10. Thus, this bus comprises 10 bits at the output of the memory controller 120 and only 1 bit at the input of each bus-switch. To detect and correct failing words, write path function 150 and read path function 160, localized in memory controller 120, are used. The read path function 160 is also used to localize a failing memory card and to forewarn the memory controller 120. As mentioned above, errors due to soft failures disappear when the data is rewritten. Thus, a test that includes rewriting the data may be performed to detect whether the error is a soft failure or a hard failure. If a hard failure is detected, the memory controller 120 could automatically insulate this failing memory card using Bus_Insulation bus 140 so that the computer user can replace it. When a hard failure occurs, the memory controller 120 sends a message through bus 190 to the computer to inform the user which memory card needs to be replaced. Bus 190 in conjunction with Bus_Insulation bus 140 also allows the computer user to inhibit a memory card so that he may change a memory card after a hard failure has been detected or for maintenance tasks. The memory system 195, that will be referred to as a memory block, allows to replace a memory card without perturbing the computer.

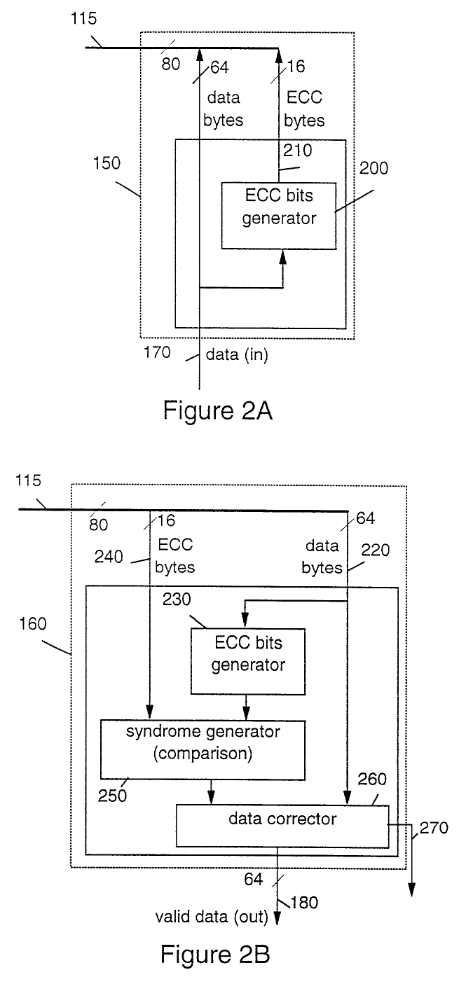

FIGS. 2A and 2B illustrate the circuits of the write path function and read path function, respectively.

The write path function contains an ECC bits generator 200 which input is the standard data input bus 170 and output is bus 210 connected to the data input/output bus 115. The standard data input bus 170 is also connected to the data input/output bus 115.

The write path function 150, schematically presented in FIG. 2A, uses the 64 bits of the data transferred from the computer to the data memory through the standard data input bus 170 to compute 16 BEC bits in the ECC bits generator 200 that are stored in the BEC memory thanks to bus 210. Thus, the data and the corresponding ECC are addressed to the memory cards through data input/output bus 115.

The read path function 160 contains an ECC bits generator 230 which the input is connected to the data input/output bus 115 through bus 220 and the output is connected to an input of a syndrome generator 250. The syndrome generator 250 is provided with a second input that is connected to the data input/output bus 115 through bus 240. The read path function 160 also contains a data corrector 260 which an input is connected to the output of the syndrome generator 250 and the second input is connected to the data input/output bus 115 through bus 220. An output of the data corrector is the standard data output bus 180 and the second output is BYTE_in_error bus 270.

To generate a valid data, i.e. a data without error, the read path function 160, schematically presented in FIG. 2B, accesses the data through the standard data input/output bus 115 and bus 220 and re-computes its corresponding BEC bits in the ECC bits generator 230. Then, it compares these evaluated BEC bits with the ones previously stored in the BEC memory and associated to this data, obtained through the standard data input/output bus 115 and bus 240, in the syndrome generator 250. According to the result of this comparison, the data is corrected or not in the data corrector 260. The localization of a failing byte can be obtained through BYTE_in_error bus 270. The 64 bits valid word is obtained on the standard data output bus 180.

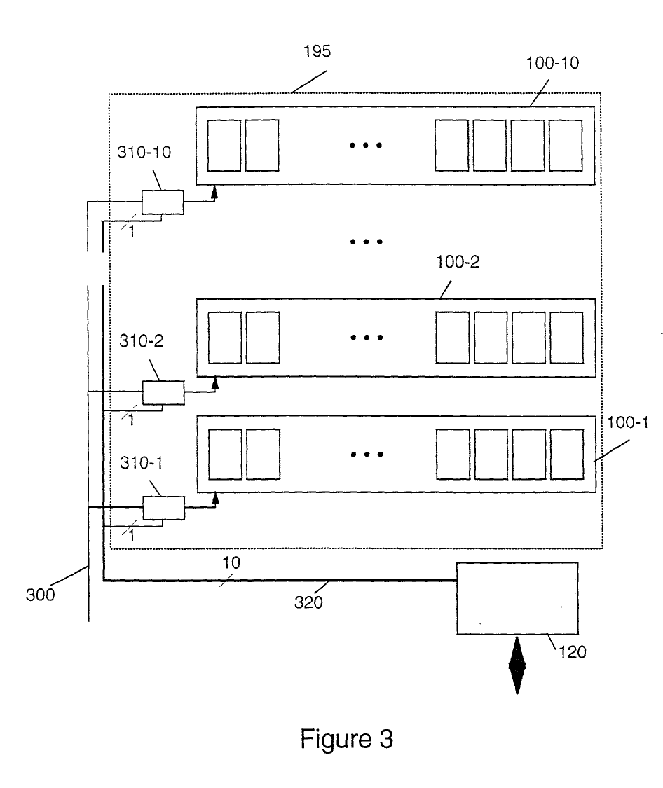

FIG. 3 illustrates the power supply circuit of the memory block 195 that still contained ten memory cards 100-1 to 100-10. A common power supply bus 300 is connected to power control modules 310-1 to 310-10 that are linked to memory cards 100-1 to 100-10, one power control module is associated to one memory card, e.g. power control module 310-1 is connected to memory card 100-1. These power control modules, acting like a bus-switch, are controlled by the memory controller 120 thanks to POWER_Enable bus 320. POWER_Enable bus 320 contains 10 bits at the output of the memory controller 120 and 1 bit at the input of each power control module so that each memory card can be electrically insulated without perturbing the others.

To avoid electronic damage, power supply and logical parts of a circuit are generally switched in two steps thus, in the preferred embodiment, two controls, POWER_Enable and BUS_Insulation, have been used. However, these two controls could be the same. Likewise, it could be possible to use one bus-switch per memory card to insulate it logically and electrically.

To illustrate the above mentioned circuit, let us consider that memory card 100-2 is failing (hard failure). Thanks to the data bytes contained in memory cards 100-1 and 100-3 to 100-8, thanks to the BEC bytes contained in memory cards 100-9 and 100-10 and thanks to the read path function 160 comprised in the memory controller 120, the unreachable bytes stored in memory card 100-2 can be retrieved. As mentioned above, a test including rewriting the data may be performed to detect whether the error is a soft failure or a hard failure. As a hard failure is detected in this example, the memory card 100-2 is to be replaced. Then, using BUS_Insulation 140 and POWER_Enable 320, memory card 100-2 can be logically and electrically insulated and thus replaced by a new memory card without perturbing the computer.

However, if a second memory card fails before the first failing memory card has been replaced or before the content of the first failing memory card has been restored, the memory system is not able to recover the data (as mentioned above, the BEC is unable to correct such kind of error). To overcome this problem, the present invention uses a backup memory card that may be used as soon as a hard failure is detected in a memory card.

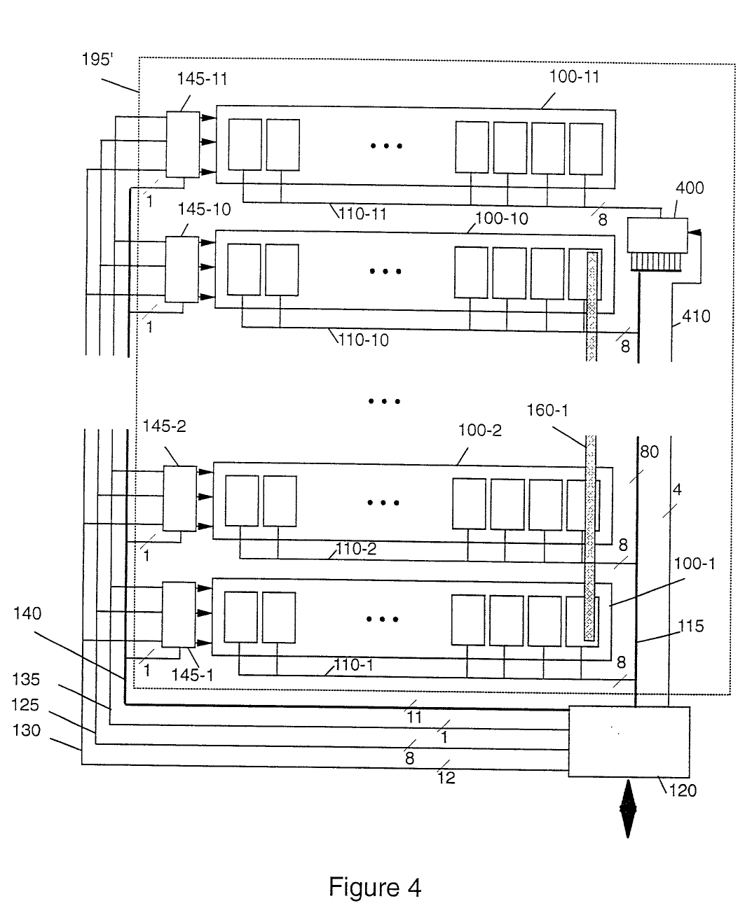

FIG. 4 presents the circuit of the present invention, based on the one described above, that comprises an additional memory card 100-11. This memory card 100-11 is connected to the common Memory_Card_Select 135, BYTE_Select 125 and address bus 130 signals and can be enabled or disabled by standard bus-switch component 145-11 controlled by BUS_Insulation signal 140 that now comprises 11 bits (one for each memory card 100-1 to 100-11). The data input/output buses of the memory chips contained within this additional memory card are connected together to create the data input/output bus 110-11 that is connected to multiplexor 400 in order to be connected to one of the data input/output buses 110-1 to 110-10 of the memory cards 100-1 to 100-10. Multiplexor 400 is controlled by DATA_Select signal 410 generated by the memory controller 120. DATA_Select signal 410 comprises 4 bits to set one of the 10 possible switch positions of multiplexor 400.

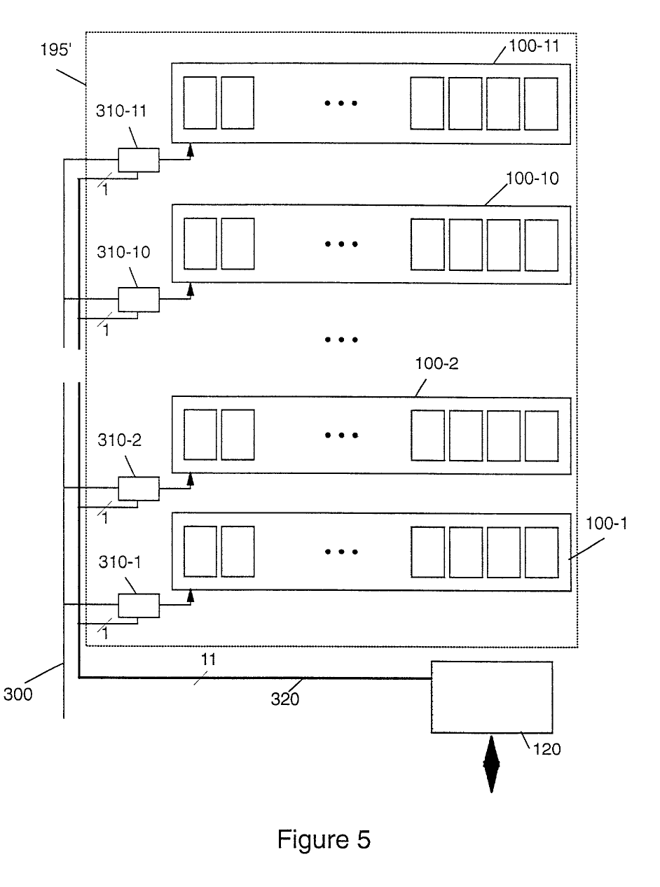

FIG. 5 illustrates the way to connect an optional power control module 310-11 that is commanded by the power supply control signal POWER_Enable 320, now comprising 11 bits (one for each memory card 100-1 to 100-11). Power control module 310-11 allows to electrically insulate memory card 100-11. Logically and electrically insulating memory card 100-11 allows to replace it without perturbing the memory system.

Thus, using the circuit of the present invention, several methods allow to increase the availability of the memory system. The simplest one includes using the additional memory card 100-11 to replace a failing memory card as soon as a hard failure occurs. Thus, if a second error occurs in another memory card, it could be corrected if the data has been written in the additional memory card after this additional memory card has replaced the first failing memory card. However, this method presents a drawback: when a hard failure occurs in a memory card it does not mean necessary that the whole content of this memory card is damaged. For example, if a hard failure occurs in a single memory chip of a memory card the whole content of the memory card is lost when the memory card is replaced by the additional memory card. To get rid of it, a second method includes using the additional memory card in conjunction with the memory card in which a hard failure has been detected: the additional memory card is used to read a word only if this word can not be recovered when using the memory card in which the hard failure has been detected. This second method includes writing the same part of a word in the memory card in which the hard failure has been detected and in the additional memory card. To read a word, the memory card in which the hard failure has been detected is enabled and the additional memory card is disabled. If the data is not recovered, i.e. errors occur in at least two memory cards (as mentioned above, the BEC is unable to correct such kind of error), the first memory card in which the hard failure has been detected is disabled and the additional memory card is enabled and another reading is performed. However, this solution still presents a drawback concerning the replacement of the first failing memory card: its content will be lost when it is removed.

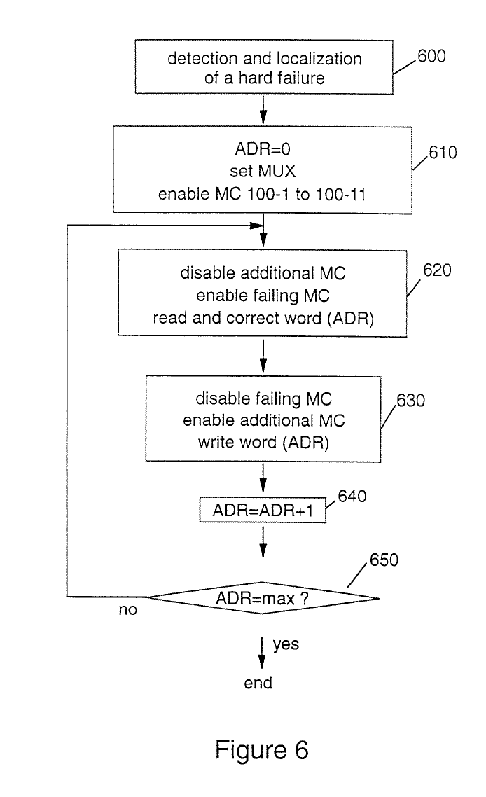

FIG. 6 shows the main steps of the algorithm that illustrates a preferred method of the present invention used in conjunction with the circuit presented in FIG. 4. It represents the copy procedure of the content of a failing memory card, referred to as MC on the drawing, in the additional one (100-11). After having detected and localized a hard failure in a memory card using read path macro 160 and the data rewriting test (box 600), an address index ADR is set to zero, the multiplexor (400) is positioned in such a way that data bus 110-11 is linked to the data bus of the failing memory card by using BYTE_in_error (270) and DATA_Select (410) signals and the memory cards 100-1 to 100-11 are enabled using Memory_Card_Select (135) and BUS_Insulation (140) signals (box 610). For sake of clarity, it is assumed that ADR index is a representation of a memory card address, i.e. an address defined by BYTE_Select (125) and address (130) signals. The additional memory card 100-11 is disabled and the failing memory card is enabled using BUS_Insulation (140) signal in order to read the data localized at address ADR (box 620). The data read by read path macro (160) is corrected if an error is detected and the part of this data corresponding to the failing memory card is stored in a standard register (not represented) that can be an external register, a memory controller register or an internal register of the computer processor. Then, the failing memory card is disabled and the additional memory card 100-11 is enabled using BUS_Insulation (140) signal and the data stored in the above mentioned register is written back in the additional memory card 100-11 at address ADR (box 630). The address ADR is then incremented by 1 (box 640). A test is performed to check if the address ADR is the maximum address that can be used (box 650). If no, a loop is performed to copy the data located at address ADR from the failing memory card to the additional memory card, as mentioned above the data read from the failing memory card is corrected if required (box 620 to 650). If ADR has reached its maximum value the process is stopped.

To illustrate the circuit described in FIG. 4 and the algorithm presented above, let us consider that a hard failure has been detected in memory card 100-2. Thanks to the coding system the data may be retrieved until a new error occurs in another memory card. To avoid this situation, the memory card 100-2 is to be changed. As it is possible that the computer user can not change the memory card 100-2 when the hard failure occurs, it could be useful to replace automatically the memory card 100-2 by the additional memory card. To that end, the content of the memory card 100-2 is corrected and copied in the additional memory card 100-11 so that the memory card 100-2 can be changed later without decreasing the computer availability. The content of the additional memory card 100-11 is copied back to the new memory card 100-2 when it is changed.

First, an address index ADR is set to zero, multiplexor is set to link the data bus 110-11 to data bus 110-2, the memory cards 100-1 to 100-10 are enabled using bus-switch components 145-1 to 145-10 and the memory card 100-11 is disabled using bus-switch component 145-11. Then, the data localized at address ADR is read from memory cards 100-1 to 100-10 and corrected if required, as explained above. Memory card 100-2 is disabled using bus-switch component 145-2 and memory card 100-11 is enabled using bus-switch component 145-11 to write the part of the data associated to memory card 100-2 in memory card 100-11. It is to be understood that if an error was detected in this part of the data, it is corrected before being memorized in memory card 100-11. Then the process is repeated until the content of memory card 100-2 has been corrected and copied in memory card 100-11. At this stage, a second error (soft failure or failure) may occur in any memory card without any damage for the memory system content. If the computer user changes the memory card 100-2 before its content has been corrected and copied in the memory card 100-11, it can be recovered.

Memory card 100-2 may be changed using bus-switch component 145-2 and power control module 310-2. When the memory card 100-2 has been changed, the content of memory card 100-11 may be copied back in the new memory card 100-2. First, the address index ADR is set to zero, the memory cards 100-1 and 100-3 to 100-11 are enabled using bus-switch components 145-1 and 145-3 to 145-11 and the memory card 100-2 is disabled using bus-switch component 145-2. Then, the data localized at address ADR is read from memory cards 100-1 and 100-3 to 100-11 and corrected if required. Memory card 100-2 is enabled using bus-switch component 145-2 and memory card 100-11 is disabled using bus-switch component 145-11 to write the part of the data associated to memory card 100-11 in memory card 100-2. Once again, it is to be understood that if an error was detected in this part of the data, it is corrected before being memorized in memory card 100-2. Then the process is repeated until the content of memory card 100-11 has been copied in memory card 100-2. Thus, at the end of the process, the failing memory card 100-2 has been changed and its content has been corrected and saved without decreasing the availability of the computer memory system.

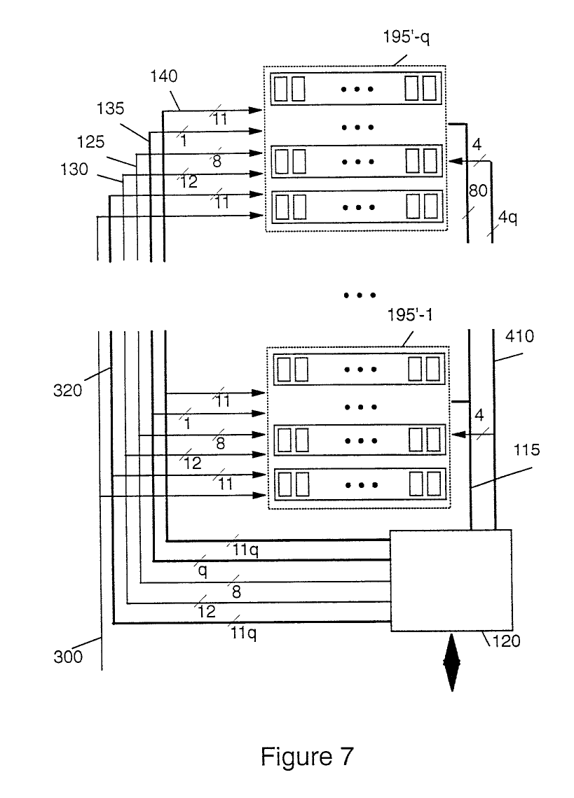

FIG. 7 shows a memory system that illustrates the way to increase the computer amount of memory using the present invention. Several above described memory blocks 195′ are connected in parallel (195′-1 to 195′-q) using the global data input/output bus 115 that is connected to the memory controller 120. The power supply bus 300, the address bus 130 and the BYTE_Select bus 125 are common for all the memory blocks. The POWER_Enable and the BUS_Insulation buses (320 and 140 respectively) control each memory card independently so they contain 11q bits at the output of the memory controller 120 and 11 bits at the input of each memory block. The Memory_Card_Select bus 135 is used to enable or disable all the memory cards of a memory block, so Memory_Card_Select bus 135 comprises q bits at the output of the memory controller 120 and 1 bit at the input of each memory block. Also, BUS_Select bus 410 that is used to control the multiplexor 400 of each memory block comprises 4q bits, i.e. 4 bits per memory block.

Using the circuit presented in FIG. 7, the access to any memory block 195′-i for read or write operations is performed by enabling all the memory cards belonging to this memory block (except the additional memory card 100-11 or the memory card that it replaces) and disabling all the other memory cards using Memory_Card_Select bus 135 and BUS_Insulation bus 140 that are managed by memory controller 120. The memory access inside a memory block is performed by memory chip selections and addresses as explained above. When the read path macro detects and corrects a failing word, the memory controller could detect whether or not the error is due to a hard failure and use the information given by the data corrector to copy its corrected content into the additional memory card, to insulate the failing memory card and to inform the user through the computer. Thus, the user may replace this failing memory card without perturbing the memory system.

In accordance with an aspect of the present invention, when an error is detected in a memorization subsystem, this memorization subsystem is insulated and replaced by a backup memorization subsystem that contains the data memorized in the failing memorization subsystem that has been corrected. When a memory card is insulated, the computer user can change this memorization subsystem without losing data and without perturbing the computer.

While the invention has been described in terms of a preferred embodiment, those skilled in the art will recognize that the invention can be practiced with other kinds of removable and independent memorization subsystems and for other tasks. In particular, the invention can be useful to upgrade the memory system where the memory cards can be replaced one by one by memory cards having greater capacities or for preventive maintenance, without turning off the computer. Also, even if the preferred embodiment is based on an additional memory card per memory block, the person skilled in the art could easily implement a circuit that comprises only one additional memory card for the whole memory system. It is also possible to use another memorization means, like a hard drive or a flash memory, to save the content of a failing memory card or a memory card to be changed in order to reload the data in the memory card after its replacement.

The present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

What is claimed is:

1. A system for accessing a memory comprising a plurality of memorization subsystems, independent and removable, said memory being adapted to store words made of n unitary elements, said system comprising:
encoding means to encode each of the n unitary element words to be stored into the memory into a n+m unitary elements word, where the m unitary elements are error correction unitary elements;
word input means for applying each of the n+m elementary elements of a word to a different memorization subsystem of said plurality of memorization subsystems, being able to apply anyone of the n+m elementary elements of a word to at least one of said plurality of memorization subsystems, referred to as backup memorization subsystem;
word output means for accessing each of the n+m elementary elements of a word from said plurality of memorization subsystems;
decoding means responsive to each n+m elementary elements word for producing an error free n unitary elements word; and,
logical insulation means associated to each of said plurality of memorization subsystems, capable of insulate logically each of said plurality of memorization subsystems.

2. The system of claim 1 further comprising information means associated to said decoding means to forewarn the user of said system when at least one of said plurality of memorization subsystems is failing.

3. The system of claim 1 further comprising information means associated to said decoding means to forewarn the user of said system when a hard failure is detected in at least one of said plurality of memorization subsystems.

4. The system according to claim 3 further comprising control means associated to said word input means and to said logical insulation means so that the user can copy the content of one of said plurality of memorization subsystems into said backup memorization subsystem.

5. The system according to claim 4 further comprising electrical insulation means associated to each of said plurality of memorization subsystems.

6. The system of claim 5 further comprising control means associated to said electrical insulation means so that the user of said system can electrically insulate at least one of said plurality of memorization subsystems.

7. The system of claim 5 further comprising information means associated to said decoding means, first control means associated to said logical insulation means and said electrical insulation means and second control means associated to said word input means so that the content of a failing memorization subsystem of said plurality of memorization subsystems in which a hard failure is detected is automatically corrected and copied into said backup memorization subsystem, said failing memorization subsystem being automatically insulated and the user of said system being informed that said failing memorization subsystem is failing and that said failing memorization subsystem is insulated.

8. The system of claim 7 wherein the content of a failing memorization subsystem is automatically corrected and copied into said backup memorization subsystem when said system for accessing a memory is not used.

9. The system of claim 7 wherein a part of the content of a failing memorization subsystem is automatically corrected and copied into said backup memorization subsystem when said system for accessing a memory is not used.

10. The system according to claim 9 wherein said encoding means and said decoding means use the 8-bits Block Error Coding algorithm.

11. The system according to claim 10 wherein each of said plurality of memorization subsystems is a standard Dual In-line Memory Modules.

12. The system according to claim 1 further comprising control means associated to said word input means and to said logical insulation means so that the user can copy the content of one of said plurality of memorization subsystems into said backup memorization subsystem.

13. The system according to claim 1 further comprising electrical insulation means associated to each of said plurality of memorization subsystems.

14. The system according to claim 1 wherein said encoding means and said decoding means use the 8-bits Block Error Coding algorithm.

15. The system according to claim 1 wherein each of said plurality of memorization subsystems is a standard Dual In-line Memory Modules.

16. A method for correcting and copying the content of one of a plurality of memorization subsystems, representing unitary elements of words, into a backup memorization subsystem, comprising:
a. setting an address index to zero and enabling the set of memorization subsystems storing unitary elements of said words;
b. disabling said backup memorization subsystem, enabling said one of said plurality of memorization subsystems, reading the word at the location defined by said address index and, if an error is detected, correcting said word using said decoding means;
c. disabling said one of said plurality of memorization subsystems, enabling said backup memorization subsystem and writing the unitary element contained in said one of said plurality of memorization subsystems, corrected if required, in said backup memorization subsystem at the location defined by said address index;
d. increasing said address index by one; and
e. comparing said address index to the maximum value that can be reached by said address index, if said address index has not reached said maximum value repeating the last 3 steps else if said address index has reached said maximum value ending the process.

17. The method of claim 16 that is automatically executed after a hard failure has been detected, said one of said plurality of memorization subsystems being the one in which the hard failure has been detected.

18. The method of claim 17 further comprising forewarning the user that a hard failure has been detected and that the content of said one of said plurality of memorization subsystems has been restored in said backup memorization subsystem.

19. The method of claim 17 further comprising:
electrically insulating said one of said plurality of memorization subsystems; and
forewarning the user that a hard failure has been detected, the content of said one of said plurality of memorization subsystems has been restored in said backup memorization subsystem and said one of said plurality of memorization subsystems has been electrically insulated.

20. A method for correcting and copying the content of a backup memory subsystem, representing unitary elements of words, into one of a plurality of memorization subsystems, comprising:
a. setting an address index to zero and enabling the set of memorization subsystems storing unitary elements of said words;
b. disabling said one of said plurality of memorization subsystems, enabling said backup memorization subsystem, reading the word at the location defined by said address index and, if an error is detected, correcting said word using said decoding means;
c. disabling said backup memorization subsystem, enabling said one of said plurality of memorization subsystems and writing the unitary element contained in said backup memorization subsystem, corrected if required, in said one of said plurality of memorization subsystems at the location defined by said address index;
d. increasing said address index by one; and
e. comparing said address index to the maximum value that can be reached by said address index, if said address index has not reached said maximum value repeating the last 3 steps else if said address index has reached said maximum value ending the process.
